(19) United States
(12) Patent Application Publication
(10) Pub. No.: US 2025/0309602 A1
(43) Pub. Date: Oct. 2, 2025

(54) GAS LASER DEVICE AND ELECTRONIC DEVICE MANUFACTURING METHOD

(71) Applicant: Gigaphoton Inc., Tochigi (JP)

(72) Inventor: Kohei KUSAYANAGI, Oyama-shi (JP)

(73) Assignee: Gigaphoton Inc., Tochigi (JP)

(21) Appl. No.: 19/047,105

(22) Filed: Feb. 6, 2025

(30) Foreign Application Priority Data
Mar. 27, 2024 (JP) 2024-052186

(51) Int. Cl. H01S 3/034

(52) U.S. Cl. CPC H01S 3/034

(57) ABSTRACT

A gas laser device includes a chamber device; and a pulse stretcher which includes a looped optical path including a beam splitter and a plurality of mirrors, and a light guide optical system, and which the pulse laser light output from the chamber device enters. The light guide system causes the pulse laser light having entered the pulse stretcher to be output from the pulse stretcher via the beam splitter. The looped optical path returns a part of the pulse laser light having entered the beam splitter to the beam splitter via the plurality of mirrors to cause the part of the pulse laser light to overlap another part thereof, and is sandwiched between a first straight line along an optical path of the pulse laser light entering the pulse stretcher and a second straight line along an optical path of the pulse laser light output from the pulse stretcher.

### CROSS-REFERENCE TO RELATED APPLICATIONS

The present application claims the benefit of Japanese Patent Application No. 2024/052186, filed on Mar. 27, 2024, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 pm to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2022/0393420
Patent Document 2: U.S. Pat. No. 6,238,063

### SUMMARY

A gas laser device according to an aspect of the present disclosure includes a chamber device including a pair of electrodes at an internal space thereof at which a laser gas is enclosed, and configured to output pulse laser light; and a pulse stretcher which includes a looped optical path including a beam splitter and a plurality of mirrors, and a light guide optical system including a plurality of light guide mirrors, and which the pulse laser light output from the chamber device enters. Here, the light guide system is configured to cause the pulse laser light having entered the pulse stretcher to be output from the pulse stretcher via the beam splitter. The looped optical path is configured to return a part of the pulse laser light having entered the beam splitter to the beam splitter via the plurality of mirrors to cause the part of the pulse laser light to overlap another part of the pulse laser light having entered the beam splitter, and is arranged to be sandwiched between a first straight line along an incoming optical path that is an optical path of the pulse laser light entering the pulse stretcher and a second straight line along an outgoing optical path that is an optical path of the pulse laser light output from the pulse stretcher.

An electronic device manufacturing method according to an aspect of the present disclosure includes outputting pulse laser light generated by a gas laser device to an exposure apparatus, and exposing a photosensitive substrate in the exposure apparatus to the pulse laser light output to the exposure apparatus to manufacture an electronic device. Here, the gas laser device includes a chamber device including a pair of electrodes at an internal space thereof at which a laser gas is enclosed, and configured to output the pulse laser light; and a pulse stretcher which includes a looped optical path including a beam splitter and a plurality of mirrors, and a light guide optical system including a plurality of light guide mirrors, and which the pulse laser light output from the chamber device enters. The light guide system being configured to cause the pulse laser light having entered the pulse stretcher to be output from the pulse stretcher via the beam splitter. The looped optical path is configured to return a part of the pulse laser light having entered the beam splitter to the beam splitter via the plurality of mirrors to cause the part of the pulse laser light to overlap another part of the pulse laser light having entered the beam splitter, and is arranged to be sandwiched between a first straight line along an incoming optical path that is an optical path of the pulse laser light entering the pulse stretcher and a second straight line along an outgoing optical path that is an optical path of the pulse laser light output from the pulse stretcher.

### BRIEF DESCRIPTION OF THE DRAWINGS

Embodiments of the present disclosure will be described below merely as examples with reference to the accompanying drawings.

FIG. 1 is a schematic diagram showing a schematic configuration example of an entire electronic device manufacturing apparatus used in an exposure process for an electronic device.

FIG. 2 is a schematic diagram showing a schematic configuration example of an entire gas laser device of a comparative example.

FIG. 3 is a schematic view of a schematic configuration example of a first light guide unit, a second light guide unit, and a pulse stretcher of the comparative example viewed obliquely from above.

FIG. 4 is a schematic view of a schematic configuration example of a case of the pulse stretcher of the comparative example viewed obliquely from below.

FIG. 5 is a schematic view showing a schematic configuration example of a sub-pulse stretcher of the comparative example.

FIG. 6 is a schematic view showing a schematic configuration example of a housing of the comparative example.

FIG. 7 is a schematic view of a schematic configuration example of the first light guide unit, the second light guide unit, and the pulse stretcher of a first embodiment as shown in FIG. 3.

FIG. 8 is a schematic view chowing a schematic configuration example of the housing of the first embodiment.

FIG. 9 is a view of a schematic configuration example of the first light guide unit, the second light guide unit, and the pulse stretcher of a second embodiment as shown in FIG. 3.

FIG. 10 is a view of a schematic configuration example of the first light guide unit, the second light guide unit, and the pulse stretcher of a third embodiment as shown in FIG. 3.

### DESCRIPTION OF EMBODIMENTS

1. Description of electronic device manufacturing apparatus used in exposure process for electronic device
2. Description of gas laser device of comparative example
2.1 Configuration
2.2 Operation
2.3 Problem
   3. Description of gas laser device of first embodiment
3.1 Configuration
3.2 Operation
3.3 Effect
   4. Description of gas laser device of second embodiment
4.1 Configuration
4.2 Effect
   5. Description of gas laser device of third embodiment
5.1 Configuration
5.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus Used in Exposure Process for Electronic Device

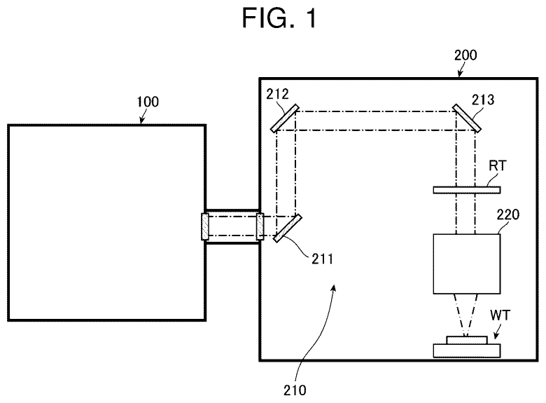

FIG. 1 is a schematic diagram showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device of a comparative example will be described. The comparative example of the present disclosure is an example recognized by the applicant as known only by the applicant, and is not a publicly known example admitted by the applicant.

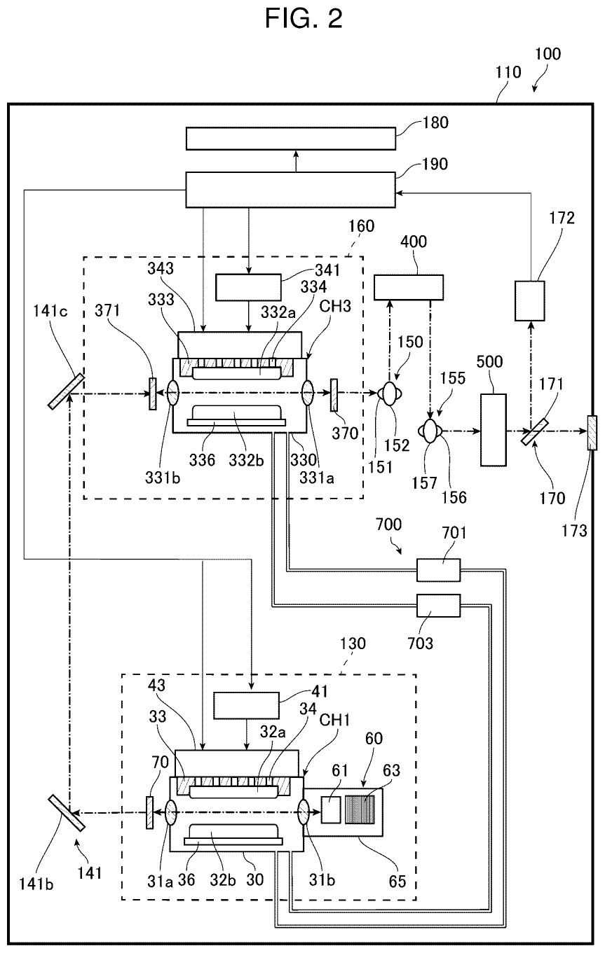

FIG. 2 is a schematic view showing a schematic configuration example of the entire gas laser device 100 of the comparative example. The gas laser device 100 is, for example, an ArF excimer laser device using a mixed gas including argon (Ar), fluorine (F₂), and neon (Ne). The gas laser device 100 outputs laser light having a center wavelength of about 193 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248 nm. The mixed gas containing Ar, F₂, and Ne which is a laser medium and the mixed gas containing Kr, F₂, and Ne which is a laser medium may be each referred to as a laser gas. In the mixed gas used in each of the ArF excimer laser device and the KrF excimer laser device, helium (He) may be used instead of Ne.

The gas laser device 100 includes a housing 110, and a laser oscillator 130 that is a master oscillator, an optical transmission unit 141, an amplifier 160 that is a power oscillator, a first light guide unit 150, a second light guide unit 155, a pulse stretcher 400, a sub-pulse stretcher 500, a detection unit 170, a display unit 180, a processor 190, and a gas module 700 arranged at an internal space of the housing 110 as a main configuration.

The laser oscillator 130 includes a chamber device CH1, a charger 41, a pulse power module 43, a line narrowing module 60, and an output coupling mirror 70 as a main configuration.

In FIG. 2, the internal configuration of the chamber device CH1 is shown as viewing from a direction substantially perpendicular to the travel direction of the laser light. The chamber device CH1 includes a housing 30, a pair of windows 31a, 31b, a pair of electrodes 32a, 32b, an insulating portion 33, a feedthrough 34, and an electrode holder portion 36 as a main configuration.

The housing 30 is supplied with the laser gas from a laser gas supply device 703 of the gas module 700 to the internal space of the housing 30 via a pipe, and the laser gas is enclosed at the internal space. The internal space is a space in which light is generated by excitation of the laser medium in the laser gas. This light travels to the windows 31a, 31b.

The window 31a is arranged at a wall surface of the housing 30 on the front side in the travel direction of the laser light from the gas laser device 100 to the exposure apparatus 200, and the window 31b is arranged at a wall surface of the housing 30 on the rear side in the travel direction. The windows 31a, 31b are calcium fluoride substrates, and surfaces of the windows 31a, 31b on the inner side and the outer side of the housing 30 are flat surfaces. Here, the windows 31a, 31b are not limited to the calcium fluoride substrate as long as being capable of transmitting the laser light.

The electrodes 32a, 32b are arranged to face each other at the internal space of the housing 30, and the longitudinal direction of the electrodes 32a, 32b are along the travel direction of the light generated by the high voltage applied between the electrode 32a and the electrode 32b. The space between the electrode 32a and the electrode 32b in the housing 30 is sandwiched between the window 31a and the window 31b. The electrodes 32a, 32b are discharge electrodes for exciting the laser medium by glow discharge. In the present example, the electrode 32a is the cathode and the electrode 32b is the anode.

The electrode 32a is supported by the insulating portion 33. The insulating portion 33 blocks an opening formed in the housing 30. The insulating portion 33 includes an insulator. Further, the feedthrough 34 made of a conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36.

The charger 41 is a DC power source device that charges a capacitor (not shown) provided in the pulse power module 43 with a predetermined voltage. The charger 41 is arranged outside the housing 30 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrodes 32a, 32b. When the high voltage is applied, discharge occurs between the electrode 32a and the electrode 32b. The energy of the discharge excites the laser medium in the housing 30. When the excited laser gas shifts to a ground level, light is emitted, and the emitted light is transmitted through the windows 31a, 31b and is output to the outside of the housing 30. Since a pulse high voltage is applied between the electrode 32a and the electrode 32b by the pulse power module 43 as described above, the laser light is pulse laser light.

The windows 31a, 31b may be inclined at the Brewster angle with respect to the travel direction of the laser light so that P polarization of the laser light is suppressed from being reflected. In the present example, the windows 31a, 31b are inclined with respect to a direction perpendicular to the travel direction of the laser light and a direction in which the electrodes 32a, 32b face each other. Therefore, the laser light output from the chamber device CH1 includes first linear polarization whose polarization direction is perpendicular to the direction in which the electrodes 32a, 32b face each other, and linear polarization whose polarization direction differs from the polarization direction of the first linear polarization is reduced from the laser light. That is, the windows 31a, 31b also serve as a polarizer that is inclined with respect to the polarization direction of the first linear polarization and reduces, from the laser light, the linear polarization whose polarization direction differs from the polarization direction of the first linear polarization.

The line narrowing module 60 includes a housing 65, and a prism 61, a grating 63, and a rotation stage (not shown) arranged at the internal space of the housing 65. An opening is formed in the housing 65, and the housing 65 is connected to the rear side of the housing 30 via the opening.

The prism 61 expands the beam width of the light output from the window 31b and causes the light to be incident on the grating 63. The prism 61 also reduces the beam width of the light reflected from the grating 63 and returns the light to the internal space of the housing 30 through the window 31b. The prism 61 is supported by the rotation stage and is rotated by the rotation stage. The incident angle of the light with respect to the grating 63 is changed by the rotation of the prism 61. Therefore, by rotating the prism 61, the wavelength of the light returning from the grating 63 to the housing 30 via the prism 61 can be selected. Although FIG. 2 shows an example in which one prism 61 is arranged, two or more prisms may be arranged.

The surface of the grating 63 is configured of a material having a high reflectance, and a large number of grooves are formed on the surface at predetermined intervals. The grating 63 is a dispersive optical element. The cross sectional shape of each groove is, for example, a right-angled triangle. The light incident on the grating 63 from the prism 61 is reflected by these grooves and diffracted in a direction corresponding to the wavelength of the light. The grating 63 is arranged in the Littrow arrangement, which causes the incident angle of the light incident on the grating 63 from the prism 61 to coincide with the diffraction angle of the diffracted light having a desired wavelength. Thus, light having a desired wavelength returns to the housing 30 via the prism 61.

The output coupling mirror 70 faces the window 31a, transmits a part of the laser light output from the window 31a, and reflects another part thereof to return to the internal space of the housing 30 through the window 31a. The output coupling mirror 70 is fixed to a holder (not shown) and is arranged at the internal space of the housing 110.

The grating 63 and the output coupling mirror 70 arranged with the housing 30 interposed therebetween configure a Fabry-Perot resonator, and the housing 30 is arranged on the optical path of the resonator. Accordingly, the resonator causes the light to resonate between both sides sandwiching the chamber device CH1.

The optical transmission unit 141 includes high reflection mirrors 141b, 141c as a main configuration. The high reflection mirrors 141b, 141c are fixed to respective holders (not shown) with inclination angles thereof adjusted, and are arranged at the internal space of the housing 110. The high reflection mirrors 141b, 141c highly reflects the laser light. The high reflection mirrors 141b, 141c are arranged on the optical path of the laser light from the output coupling mirror 70. The laser light is reflected by the high reflection mirrors 141b, 141c and travels to a rear mirror 371 of the amplifier 160. At least a part of the laser light is transmitted through the rear mirror 371.

The amplifier 160 amplifies the energy of the laser light output from the laser oscillator 130. The basic configuration of the amplifier 160 is substantially the same as that of the laser oscillator 130. In order to distinguish the components of the amplifier 160 from the components of the laser oscillator 130, the chamber device, the housing, the pair of windows, the pair of electrodes, the insulating portion, the feedthrough, the electrode holder portion, the charger, the pulse power module, and the output coupling mirror of the amplifier 160 are described as a chamber device CH3, a housing 330, a pair of window 331a, 331b, a pair of electrodes 332a, 332b, an insulating portion 333, a feedthrough 334, an electrode holder portion 336, a charger 341, a pulse power module 343, and an output coupling mirror 370. The electrodes 332a, 332b cause discharge for amplifying the laser light from the laser oscillator 130. The direction in which the electrodes 332a, 332b face each other is a direction perpendicular to the polarization direction of the first linear polarization in the laser light from the laser oscillator 130.

The windows 331a, 331b may be inclined with respect to the polarization direction of the first linear polarization so that the first linear polarization in the laser light is incident thereon as P polarization and an incident angle θ of the laser light becomes the Brewster angle. Owing to the inclination of the windows 331a, 331b, the laser light output from the chamber device CH3 includes first linear polarization, and linear polarization whose polarization direction differs from the first linear polarization is reduced from the laser light. That is, similarly to the windows 31a, 31b, the windows 331a, 331b also each serve as a polarizer that is inclined with respect to the polarization direction of the first linear polarization and reduce, from the laser light, the linear polarization whose polarization direction differs from the polarization direction of the first linear polarization. The outer shape of the laser light output from the windows 331a, 331b may be a rectangular shape elongated in a direction in which the pair of electrodes 332a, 332b face each other. Similarly to the pulse power module 43, the pulse power module 343 is a voltage application circuit.

The amplifier 160 is mainly different from the laser oscillator 130 in that the line narrowing module 60 is not included and a rear mirror 371 is included.

The rear mirror 371 is provided between the high reflection mirror 141c and the window 331b and faces to both thereof. The rear mirror 371 transmits a part of the laser light from the laser oscillator 130 toward the space between the electrodes 332a, 332b, and reflects the laser light amplified by the electrodes 332a, 332b toward the space between the electrodes 332a, 332b.

The output coupling mirror 370 is provided between the window 331a and a high reflection mirror 151 and faces to both thereof. The output coupling mirror 370 reflects a part of the laser light amplified by the electrodes 332a, 332b and output toward the space between the electrodes 332a, 332b, and transmits another part of the laser light toward the high reflection mirror 151. For this purpose, the surface of the output coupling mirror 370 facing the window 331a is coated with a partial reflection film having a predetermined reflectance.

The output coupling mirror 370 may have a circular shape. A surface facing the window 331a and a surface opposite thereto of the output coupling mirror 370 are flat surfaces. The configuration of the rear mirror 371 is similar to that of the output coupling mirror 70.

The rear mirror 371 and the output coupling mirror 370 arranged with the housing 330 interposed therebetween configure a resonator in which the laser light amplified by the electrodes 332a, 332b resonates. The housing 330 is arranged on the optical path of the resonator. The laser light output from the window 331a of the housing 330 is incident on the output coupling mirror 370 and a part of the laser light is reflected by the output coupling mirror 370. The laser light reflected by the output coupling mirror 370 returns to the internal space of the housing 330 via the window 331a, and is output from the window 331b. The laser light output from the window 331b is reflected by the rear mirror 371 and returns to the internal space of the housing 330 through the window 331b. Thus, the laser light output from the housing 330 reciprocates between the rear mirror 371 and the output coupling mirror 370. The reciprocating laser light is amplified every time the laser light passes through a discharge space between the electrode 332a and the electrode 332b. That is, the resonator resonates light between both sides sandwiching the chamber device CH3, and the output coupling mirror 370 is arranged on one side of sandwiching the chamber device CH3. A part of the amplified laser light is transmitted through the output coupling mirror 370. The laser light transmitted through the output coupling mirror 370 travels to the high reflection mirror 151. As described above, the laser light traveling from the output coupling mirror 370 to the high reflection mirror 151 is pulse laser light.

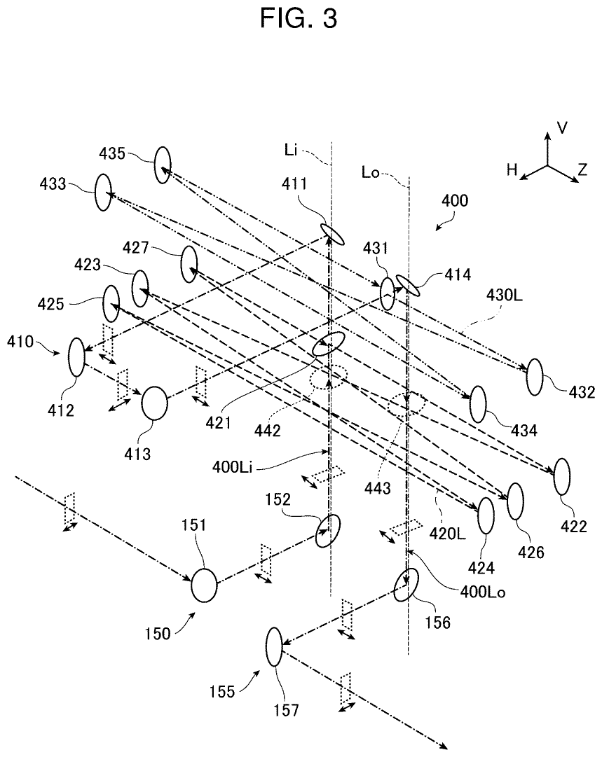

FIG. 3 is a schematic view of a schematic configuration example of the first light guide unit 150, the second light guide unit 155, and the pulse stretcher 400 of the comparative example viewed obliquely from above. The first light guide unit 150 includes high reflection mirrors 151, 152 as a main configuration. In the following, a direction in which the laser light propagates and which is parallel to the optical axis direction of the laser light output from the window 331a of the chamber device CH3 and transmitted through the output coupling mirror 370 is described as a Z direction, a height direction of the gas laser device 100 is described as a V direction, and a direction perpendicular to the V direction and the Z direction is described as an H direction. The V direction is a direction perpendicular to the Z direction and substantially parallel to the vertical direction and directed upward. Therefore, in the present example, the optical axis direction of the laser light output from the window 331a and transmitted through the output coupling mirror 370 is substantially parallel to the horizontal direction.

The high reflection mirrors 151, 152 are fixed to respective holders (not shown) with inclination angles thereof adjusted, and highly reflects the laser light. In FIG. 3, the outer shape of the laser light is indicated by dotted lines, and the polarization direction of the first linear polarization of the laser light is indicated by solid arrows. The high reflection mirror 151 is arranged on the optical path of the laser light from the output coupling mirror 370. The high reflection mirror 151 reflects the laser light from the output coupling mirror 370 in the −H direction. The high reflection mirror 152 is arranged on the optical path of the laser light reflected by the high reflection mirror 151, and is located on the −H direction side with respect to the optical axis of the laser light transmitted through the output coupling mirror 370. The high reflection mirror 152 reflects the laser light reflected by the high reflection mirror 151 in the V direction, and the laser light enters the pulse stretcher 400.

The pulse stretcher 400 extends the pulse width of the laser light entering the pulse stretcher 400 from the first light guide unit 150, and outputs the laser light whose pulse width has been extended toward the second light guide unit 155.

The pulse stretcher 400 of the present example includes a light guide optical system 410, two looped optical paths 420L, 430L, and a case (not shown) as a main configuration, and is arranged on the V direction side with respect to the optical axis of the laser light transmitted through the output coupling mirror 370. The light guide optical system 410 and the looped optical paths 420L, 430L are accommodated in the case.

The light guide optical system 410 of the present example includes four light guide mirrors 411, 412, 413, 414 as a main configuration. The light guide mirrors 411, 412, 413, 414 are supported by the case of the pulse stretcher 400 with the inclination angles thereof adjusted, and highly reflect the laser light. The light guide mirror 411 is located on the −H direction side with respect to the optical axis of the laser light transmitted through the output coupling mirror 370, and is arranged on the optical path of the laser light reflected by the high reflection mirror 152 and entering the pulse stretcher 400. The light guide mirror 411 reflects the laser light having entered the pulse stretcher 400 in the H direction. The light guide mirror 412 is arranged on the optical path of the laser light reflected by the light guide mirror 411 and on the side opposite to the light guide mirror 411 with respect to the optical axis of the laser light transmitted through the output coupling mirror 370. The light guide mirror 412 reflects the laser light reflected by the light guide mirror 411 in the Z direction. The light guide mirror 413 is arranged on the optical path of the laser light reflected by the light guide mirror 412. The light guide mirror 413 reflects the laser light reflected by the light guide mirror 412 in the —H direction. The light guide mirror 414 is arranged on the optical path of the laser light reflected by the light guide mirror 413 and on the —H direction side with respect to the optical axis of the laser light transmitted through the output coupling mirror 370. The light guide mirror 414 and the light guide mirror 411 are aligned in the Z direction. The light guide mirror 414 reflects the laser light reflected by the light guide mirror 413 in the —V direction, and the laser light is output from the pulse stretcher 400. The light guide optical system 410 having such a configuration reflects the laser light having entered the pulse stretcher 400 sequentially by the plurality of light guide mirrors 411, 412, 413, 414, and causes the laser light to be output from the pulse stretcher 400 on the side which the laser light enters.

The looped optical path 420L of the present example includes a beam splitter 421 and six mirrors 422, 423, 424, 425, 426, 427. The beam splitter 421 is arranged on the optical path of the laser light having reflected by the high reflection mirror 152, having entered the pulse stretcher 400, and traveling toward the light guide mirror 411 among the optical paths of the laser light in the light guide optical system 410, and is supported by the case of the pulse stretcher 400. The beam splitter 421 separates the incident laser light into two beams, transmits one separated beam toward the light guide mirror 411 to cause the one separated beam to propagate on the optical path of the light guide optical system 410, and reflects the other separated beam toward the mirror 422.

The mirrors 422 to 427 are concave mirrors and are supported by the case of the pulse stretcher 400. The mirrors 422, 424, 426 are arranged on the Z direction side with respect to the light guide mirrors 411 to 414, and are aligned in the H direction in the order of the mirrors 422, 426, 424. The mirrors 423, 425, 427 are arranged on the —Z direction side with respect to the light guide mirrors 411 to 414, and are aligned in the H direction in the order of the mirrors 427, 423, 425. The mirror 422 and the mirror 427 face each other in a direction parallel to the Z direction, and the beam splitter 421 is located between the mirror 422 and the mirror 427. The mirror 424 and the mirror 425 face each other in a direction parallel to the Z direction, and the mirror 426 and the mirror 423 face each other in a direction parallel to the Z direction.

The mirrors 422 to 427 sequentially reflect the laser light reflected by the beam splitter 421 and return the laser light to the beam splitter 421. Specifically, the mirror 422 reflects the laser light reflected by the beam splitter 421 toward the mirror 423. The mirror 423 reflects the laser light reflected by the mirror 422 toward the mirror 424. The mirror 424 reflects the laser light reflected by the mirror 423 toward the mirror 425. The mirror 425 reflects the laser light reflected by the mirror 424 toward the mirror 426. The mirror 426 reflects the laser light reflected by the mirror 425 toward the mirror 427. The mirror 427 reflects the laser light reflected by the mirror 426 toward the beam splitter 421, and causes the laser light to be incident on the beam splitter 421 from a surface opposite to the surface on which the laser light reflected by the high reflection mirror 152 is incident. Thus, the looped optical path 420L, which is an optical path of the laser light returning from the beam splitter 421 to the beam splitter 421 via the mirrors 422 to 427, is formed, and the looped optical path 420L spreads in the H direction and the Z direction.

The beam splitter 421 reflects a part of the laser light reflected by the mirror 427 and returned to the beam splitter 421 toward the light guide mirror 411, and transmits the other part toward the mirror 422. The transmitted laser light propagates through the looped optical path 420L. Thus, the laser light is reflected six times in the looped optical path 420L to make one turn thereof, and circulates on the looped optical path 420L to make one or more turns.

The laser light returning to the beam splitter 421 after making one turn of the looped optical path 420L, separated by the beam splitter 421, and traveling toward the light guide mirror 411 travels from the beam splitter 421 toward the light guide mirror 411 as being delayed by a predetermined time period as compared with the laser light traveling toward the light guide mirror 411 as being transmitted through the beam splitter 421 without traveling to the mirror 422. The laser light traveling from the beam splitter 421 toward the light guide mirror 411 delayed by the predetermined time period overlaps a part of the laser light traveling toward the light guide mirror 411 as being transmitted through the beam splitter 421 without traveling to the mirror 422. That is, the laser light returning to the beam splitter 421 is separated into laser light to overlap a part of one of the beams of the laser light having separated by the beam splitter 421 and laser light to be reflected sequentially by the mirrors 422 to 427. The overlapping of the laser light occurs every time the laser light makes one turn of the looped optical path 420L, and the laser light having the pulse width extended by the overlapping of the laser light travels toward the light guide mirror 411 and propagates through the light guide optical system 410. That is, the looped optical path 420L is configured such that a part of the laser light incident on the beam splitter 421 is returned to the beam splitter 421 via the mirrors 422 to 427, and is overlapped on another part of the laser light incident on the beam splitter 421.

The looped optical path 430L of the present example includes a beam splitter 431 and four mirrors 432, 433, 434, 435. The beam splitter 431 is arranged on the optical path of the laser light reflected by the light guide mirror 413 and traveling toward the light guide mirror 414 among the optical paths of the laser light in the light guide optical system 410, and is supported by the case of the pulse stretcher 400. The beam splitter 431 separates the incident laser light into two beams, transmits one separated beam toward the light guide mirror 414 to cause the one separated beam to propagate on the optical path of the light guide optical system 410, and reflects the other separated beam toward the mirror 432.

The mirrors 432 to 435 are concave mirrors and are supported by the case of the pulse stretcher 400. The mirrors 432, 434 are arranged on the Z direction side with respect to the light guide mirrors 411 to 414, and are aligned in the H direction in the order of the mirrors 432, 434. The mirrors 433, 435 are arranged on the −Z direction side with respect to the light guide mirrors 411 to 414, and are aligned in the H direction in the order of the mirrors 435, 433. The mirror 432 and the mirror 435 face each other in a direction parallel to the Z direction, and the beam splitter 431 is located between the mirror 432 and the mirror 435. The mirror 433 and the mirror 434 face each other in a direction parallel to the Z direction. The mirrors 433, 434 are located on the H direction side with respect to the mirrors 422, 427 on the looped optical path 420L.

The mirrors 432 to 435 sequentially reflect the laser light reflected by the beam splitter 431 in the order of the mirrors 432 to 435. The mirror 435 reflects the laser light reflected by the mirror 434 toward the beam splitter 431, and causes the laser light to be incident on the beam splitter 431 from a surface opposite to a surface on which the laser light reflected by the light guide mirror 413 is incident. Thus, the looped optical path 430L, which is an optical path of the laser light returning from the beam splitter 431 to the beam splitter 431 via the mirrors 432 to 435, is formed. The looped optical path 430L spreads in the H direction and the Z direction. The optical path length of the looped optical path 430L is shorter than the optical path length of the looped optical path 420L. Further, the looped optical path 430L is located above the looped optical path 420L, and the looped optical path 430L and the looped optical path 420L overlap each other in the vertical direction.

The beam splitter 431 reflects a part of the laser light reflected by the mirror 435 and returned to the beam splitter 431 toward the light guide mirror 414, and transmits the other part toward the mirror 432. The transmitted laser light propagates through the looped optical path 430L. Thus, the laser light is reflected four times in the looped optical path 430L to make one turn thereof, and circulates on the looped optical path 430L to make one or more turns.

In the looped optical path 430L described above, similarly to the looped optical path 420L, the laser light traveling from the beam splitter 431 toward the light guide mirror 414 delayed by a predetermined time period overlaps a part of the laser light traveling from the beam splitter 431 toward the light guide mirror 414. The overlapping of the laser light occurs every time the laser light makes one turn of the looped optical path 430L. The laser light having the pulse width extended by the overlapping of the laser light travels toward the light guide mirror 414 and propagates through the light guide optical system 410. That is, the looped optical path 430L is configured such that a part of the laser light incident on the beam splitter 431 is returned to the beam splitter 431 via the mirrors 432 to 435, and is overlapped on another part of the laser light incident on the beam splitter 431.

The laser light whose pulse width is thus extended by the looped optical paths 420L, 430L is output from the pulse stretcher 400 toward the second light guide unit 155.

The second light guide unit 155 of the present example mainly includes high reflection mirrors 156, 157 as a main configuration. The high reflection mirrors 156, 157 are fixed to respective holders (not shown) with inclination angles thereof adjusted, and highly reflects the laser light. The high reflection mirror 156 is arranged on the optical path of the laser light output from the pulse stretcher 400, and is located on the —H direction side with respect to the optical axis of the laser light transmitted through the output coupling mirror 370. The high reflection mirror 156 and the high reflection mirror 152 are aligned in the Z direction. The high reflection mirror 156 reflects the laser light output from the pulse stretcher 400 in the H direction. The high reflection mirror 157 is arranged on the optical path of the laser light reflected by the high reflection mirror 156, and the high reflection mirror 157 and the high reflection mirror 151 are aligned in the Z direction. The high reflection mirror 157 reflects the laser light reflected by the high reflection mirror 156 in the Z direction, and the laser light travels to the sub-pulse stretcher 500. The optical axis of the laser light traveling from the high reflection mirror 157 to the sub-pulse stretcher 500 may substantially coincide with the optical axis of the laser light transmitted through the output coupling mirror 370, or the optical axis of the laser light transmitted through the output coupling mirror 370 may be parallel to the optical axis of the laser light traveling to the sub-pulse stretcher 500 and may be shifted in the ±V direction or the ±Z direction.

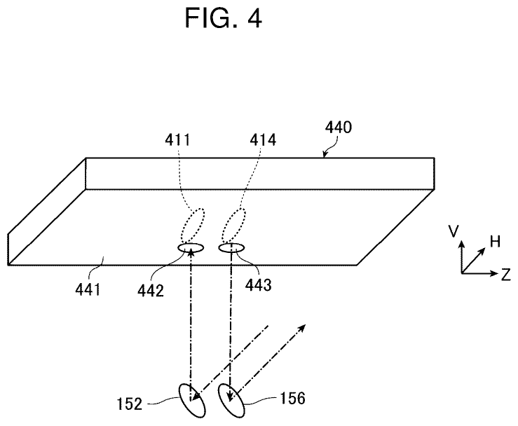

FIG. 4 is a schematic view of a schematic configuration example of a case 440 of the pulse stretcher 400 of the comparative example viewed obliquely from below.

As shown in FIG. 4, the case 440 is a box-shaped member having a space therein, and is supported by a main body portion of the housing 110, which will be described later. In the present example, the case 440 has a rectangular parallelepiped shape elongated in the Z direction. A lower wall 441 of the case 440 is provided with an inlet hole 442 and an outlet hole 443, and the inlet hole 442 and the outlet hole 443 are aligned in the Z direction. The laser light traveling from the high reflection mirror 152 toward the light guide mirror 411 passes through the inlet hole 442 and enters the case 440. Further, the laser light traveling from the light guide mirror 414 toward the high reflection mirror 156 passes through the outlet hole 443 and is output from the inside of the case 440. Among the optical path of the laser light traveling from the high reflection mirror 152 toward the light guide mirror 411, a section thereof from the inlet hole 442 to the high reflection mirror 152 is an incoming optical path 400Li which is an optical path of the laser light entering the pulse stretcher 400, and the incoming optical path 400Li is substantially parallel to the V direction. Among the optical path of the laser light traveling from the light guide mirror 414 toward the high reflection mirror 156, a section thereof from the outlet hole 443 to the high reflection mirror 156 is an outgoing optical path 400Lo which is an optical path of the laser light output from the pulse stretcher 400, and the outgoing optical path 400Lo is substantially parallel to the V direction. In FIG. 3, a first straight line Li along the incoming optical path 400Li and a second straight line Lo along the outgoing optical path 400Lo are indicated by broken lines.

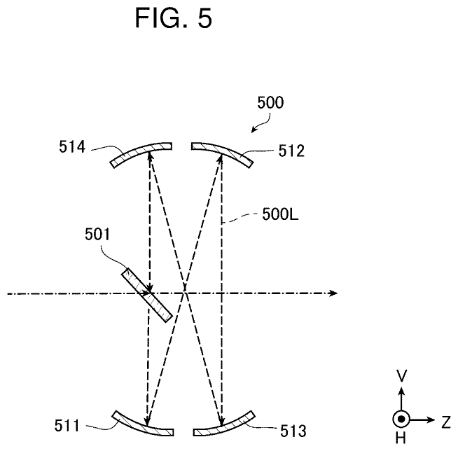

FIG. 5 is a schematic view showing a schematic configuration example of the sub-pulse stretcher 500 of the comparative example. As shown in FIG. 5, the sub-pulse stretcher 500 of the present example includes a beam splitter 501, four mirrors 511, 512, 513, 514, and a case (not shown). The beam splitter 501 is arranged on the optical path of the laser light reflected by the high reflection mirror 157, and is supported by the case of the sub-pulse stretcher 500. The beam splitter 501 separates the laser light reflected by the high reflection mirror 157 into two beams, reflects the one separated beam toward the mirror 511, and transmits the other separated beam toward the beam splitter 171.

The mirrors 511 to 514 are concave mirrors and are supported by the case of the sub-pulse stretcher 500. The mirrors 511, 513 are arranged on the —V direction side with respect to the optical axis of the laser light reflected by the high reflection mirror 157, and are aligned in the Z direction in the order of the mirrors 511, 513. The mirrors 512, 514 are arranged on the V direction side with respect to the optical axis of the laser light reflected by the high reflection mirror 157, and are aligned in the Z direction in the order of the mirrors 514, 512. The mirror 511 and the mirror 514 face each other in a direction parallel to the V direction, and the beam splitter 501 is located between the mirror 511 and the mirror 514. The mirror 512 and the mirror 513 face each other in a direction parallel to the V direction.

The mirrors 511 to 514 sequentially reflect the laser light reflected by the beam splitter 501 in the order of the mirrors 511 to 514, and return the laser light to the beam splitter 501. Since the beam splitter 501 is located between the mirror 511 and the mirror 514, the laser light reflected by the mirror 514 is incident on the beam splitter 501 from a surface opposite to a surface on which the laser light reflected by the high reflection mirror 157 is incident. In the sub-pulse stretcher 500 having such a configuration, the looped optical path 500L, which is an optical path of the laser light returning from the beam splitter 501 to the beam splitter 501 via the mirrors 511 to 514, is formed.

The beam splitter 501 reflects a part of the laser light reflected by the mirror 514 and returned to the beam splitter 501 toward the beam splitter 171, and transmits the other part toward the mirror 511. The transmitted laser light propagates through the looped optical path 500L. Thus, in the sub-pulse stretcher 500, the laser light is reflected four times in the looped optical path 500L to make one turn thereof, and circulates on the looped optical path 500L to make one or more turns.

In the looped optical path 500L, similarly to the looped optical paths 420L, 430L, the laser light traveling from the beam splitter 501 toward the beam splitter 171 delayed by a predetermined time period overlaps a part of the laser light traveling from the beam splitter 501 toward the beam splitter 171. The overlapping of the laser light occurs every time the laser light makes one turn of the looped optical path 430L. The laser light having the pulse width extended by the overlapping of the laser light is output from the sub-pulse stretcher 500 and travels to the detection unit 170.

The detection unit 170 includes a beam splitter 171 and an optical sensor 172 as a main configuration.

The beam splitter 171 is arranged on the optical path of the laser light output from the sub-pulse stretcher 500. The beam splitter 171 transmits the laser light output from the sub-pulse stretcher 500 toward an output window 173 with a high transmittance, and reflects a part of the laser light toward a light receiving surface of the optical sensor 172.

The optical sensor 172 measures a pulse energy of the laser light incident on the light receiving surface of the optical sensor 172. The optical sensor 172 is electrically connected to the processor 190, and outputs a signal indicating the measured pulse energy to the processor 190. The processor 190 controls the voltage to be applied to the electrodes 32a, 32b of the amplifier 160 based on the signal.

The output window 173 is provided in a wall of the housing 110. The light transmitted through the beam splitter 171 is output from the output window 173 to the exposure apparatus 200 outside the housing 110. The laser light is, for example, pulse laser light having a center wavelength of 193.4 nm.

The display unit 180 is a monitor that displays a state of control by the processor 190 based on a signal from the processor 190. The display unit 180 may be arranged outside the housing 110.

The processor 190 of the present disclosure is a processing device including a storage device in which a control program is stored and a central processing unit (CPU) that executes the control program. The processor 190 is specifically configured or programmed to perform various processes included in the present disclosure. The processor 190 controls the entire gas laser device 100. The processor 190 is electrically connected to an exposure processor (not shown) of the exposure apparatus 200, and transmits and receives various signals to and from the exposure processor.

The gas module 700 includes a laser gas exhaust device 701 and a laser gas supply device 703. The laser gas exhaust device 701 and the laser gas supply device 703 are electrically connected to the processor 190 with signal lines (not shown). The laser gas exhaust device 701 includes an exhaust pump (not shown), and exhausts the laser gas from the internal spaces of the housings 30, 330 via a pipe by suction of the exhaust pump according to a control signal from the processor 190. The laser gas supply device 703 supplies the laser gas from a laser gas supply source (not shown) arranged outside the housing 110 to the internal spaces of the housings 30, 330 via a pipe according to a control signal from the processor 190.

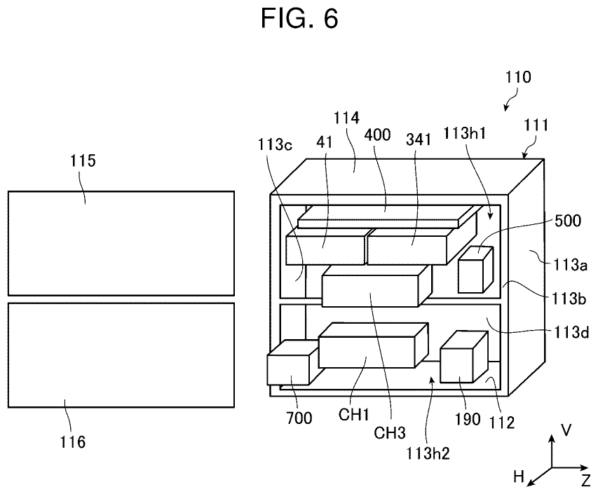

FIG. 6 is a schematic view showing a schematic configuration example of the housing 110 of the comparative example. As shown in FIG. 6, the housing 110 of the present example includes a main body portion 111 and two maintenance panels 115, 116 as a main configuration. The main body portion 111 is a box-shaped member having a space therein, and various devices such as the laser oscillator 130 and the amplifier 160 described above are accommodated at the internal space. In the present example, the main body portion 111 has a rectangular parallelepiped shape. The main body portion 111 includes a rectangular lower wall 112 elongated in the Z direction, four rectangular side walls 113a to 113d connected to four sides of the lower wall 112 respectively, and a rectangular upper wall 114 faced to the lower wall 112 and connected to the side walls 113a to 113d. The side wall 113a and the side wall 113c face each other in a direction parallel to the Z direction, and the side wall 113a is located on the Z direction side with respect to the side wall 113c. The side wall 113b and the side wall 113d face each other in a direction parallel to the H direction, and the side wall 113b is located on the H direction side with respect to the side wall 113d. Two openings 113h1, 113h2 aligned in the vertical direction are formed in the side wall 113b, and the openings 113h1, 113h2 allow various devices accommodated at the internal space to be taken in and out. The outer shape of the openings 113h1, 113h2 have a rectangular shape elongated in the Z direction. In FIG. 6, the chamber devices CH1, CH3, the processor 190, the pulse stretcher 400, the sub-pulse stretcher 500, the chargers 41, 341, and the gas module 700 are schematically shown as the various devices.

The maintenance panels 115, 116 are members that block the openings 113h1, 113h2. The maintenance panels 115, 116 are rectangular plate-shaped members elongated in the Z direction, and are attached to the side wall 113b of the main body portion 111 in a detachably attachable manner. The position, number, shape, and the like of the openings 113h1, 113h2 are not limited.

As described above, the high reflection mirror 152, the light guide mirror 411, the light guide mirror 414, and the high reflection mirror 156 are located on the —H direction side with respect to the optical axis of the laser light transmitted through the output coupling mirror 370. The optical axis of the laser light is substantially parallel to the Z direction, and the maintenance panels 115, 116 are attached to the side wall 113b. Therefore, the incoming optical path 400Li and the outgoing optical path 400Lo of the pulse stretcher 400 are located on the side opposite to the maintenance panels 115, 116 side with respect to the optical axis of the laser light transmitted through the output coupling mirror 370. When a surface where the side wall 113d of the housing 110 is located is defined as the rear surface and the position on the side opposite to the maintenance panels 115,116 side is defined as being on the rear surface side, the incoming optical path 400Li and the outgoing optical path 400Lo are located on the rear surface side with respect to the optical axis of the laser light transmitted through the output coupling mirror 370.

### 2.2 Operation

Next, operation of the gas laser device 100 of the comparative example will be described.

In a state before the gas laser device 100 outputs the laser light, the laser gas is supplied from the laser gas supply device 703 to the internal spaces of the housings 30, 330.

Before the gas laser device 100 outputs the laser light, the processor 190 receives a signal indicating a target energy Et and a signal indicating a light emission trigger from the exposure processor. The target energy Et is a target value of the energy of the laser light to be used in the exposure process. The processor 190 sets a predetermined charge voltage to the charger 41 so that the energy E becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, and is amplified every time passing through the discharge space at the internal space of the housing 30, so that laser oscillation occurs. The laser light includes the first linear polarization, and linear polarization whose polarization direction differs from the first linear polarization is reduced from the laser light transmitted through the windows 31a, 31b. A part of the laser light is transmitted through the output coupling mirror 70, is reflected by the high reflection mirrors 141b, 141c, is transmitted through the rear mirror 371 and the window 331b, and travels into the housing 330.

The processor 190 turns ON the switch of the pulse power module 343 so that discharge occurs when the laser light from the laser oscillator 130 travels to the discharge space in the housing 330. That is, the processor 190 controls the pulse power module 343 such that a high voltage is applied to the electrodes 332a, 332b after a predetermined delay time elapses from the timing at which the switch of the pulse power module 43 is turned ON.

Thus, the laser light having entered the amplifier 160 is amplified in the amplifier 160. Further, the laser light traveling to the internal space of the housing 330 is transmitted through the windows 331a, 331b as described above and travels to the rear mirror 371 and the output coupling mirror 370. Thus, the laser light having a predetermined wavelength reciprocates between the rear mirror 371 and the output coupling mirror 370. The laser light includes the first linear polarization, and linear polarization whose polarization direction differs from the first linear polarization is reduced from the laser light transmitted through the windows 331a, 331b. Further, the laser light is amplified every time passing through the discharge space at the internal space of the housing 330, and a part of the laser light becomes amplified laser light.

The amplified laser light from the amplifier 160 is transmitted through the output coupling mirror 370 and travels to the high reflection mirror 151. The laser light includes the first linear polarization whose polarization direction is parallel to the H direction, is incident on the high reflection mirror 151 so that the first linear polarization becomes P polarization, and is reflected by the high reflection mirror 151 toward the high reflection mirror 152. The laser light reflected by the high reflection mirror 151 is incident on the high reflection mirror 152 so that the first linear polarization in the laser light becomes S polarization, is reflected by the high reflection mirror 152 in the V direction, and enters the pulse stretcher 400.

The laser light entering the pulse stretcher 400 is incident on the light guide mirror 411 so that the first linear polarization in the laser light becomes S polarization, and is reflected by the light guide mirror 411 toward the light guide mirror 412. The laser light reflected by the light guide mirror 411 is incident on the light guide mirror 412 so that the first linear polarization in the laser light becomes P polarization, and is reflected by the light guide mirror 412 toward the light guide mirror 413. The laser light reflected by the light guide mirror 413 is incident on the light guide mirror 414 so that the first linear polarization in the laser light becomes P polarization, is reflected by the light guide mirror 414, and is output from the lower side of the pulse stretcher 400 on which the laser light is incident. Further, in the pulse stretcher 400, the pulse width of the laser light that propagates as being reflected sequentially by the light guide mirrors 411 to 414 of the light guide optical system 410 in this manner is extended by the respective looped optical paths 420L, 430L. Then, the laser light whose pulse width has been extended is output from the pulse stretcher 400, and travels to the high reflection mirror 156. The laser light is incident on the high reflection mirror 156 so that the first linear polarization in the laser light becomes S polarization, and is reflected by the high reflection mirror 156 toward the high reflection mirror 157. The laser light reflected by the high reflection mirror 156 is incident on the high reflection mirror 157 so that the first linear polarization in the laser light becomes P polarization, is reflected by the high reflection mirror 157 in the Z direction, and enters the sub-pulse stretcher 500.

The pulse width of the laser light entering the sub-pulse stretcher 500 is extended by the sub-pulse stretcher 500, and the laser light whose pulse width is extended travels to the beam splitter 171.

A part of the laser light having traveled to the beam splitter 171 is transmitted through the beam splitter 171 and the output window 173 and travels to the exposure apparatus 200, while another part is reflected by the beam splitter 171 and travels to the optical sensor 172.

The optical sensor 172 measures the energy E of the received laser light. The optical sensor 172 outputs a signal indicating the measured energy E to the processor 190. The processor 190 performs feedback control on the charge voltages of the chargers 41, 341 so that a difference DE between the energy E and the target energy Et is within an allowable range.

### 2.3 Problem

There may be a case that the pulse stretcher 400 is positioned with reference to the incoming optical path 400Li and the outgoing optical path 400Lo. In this case, if the positions of the mirrors 422 to 427 and 432 to 435 configuring the looped optical paths 420L, 430L with respect to the incoming optical path 400Li and the outgoing optical path 400Lo deviate from designed positions, the performance of the laser light may deviate from a designed value. Therefore, there is a demand for suppressing the performance of the laser light from deviating from the designed value.

Therefore, in the following embodiments, a gas laser device capable of suppressing the performance of the laser light from deviating from the designed value is exemplified.

### 3. Description of Gas Laser Device of First Embodiment

Next, the gas laser device 100 of a first embodiment will be described. Any component same as that described above is denoted by an identical reference sign, and duplicate description thereof is omitted unless specific description is needed.

### 3.1 Configuration

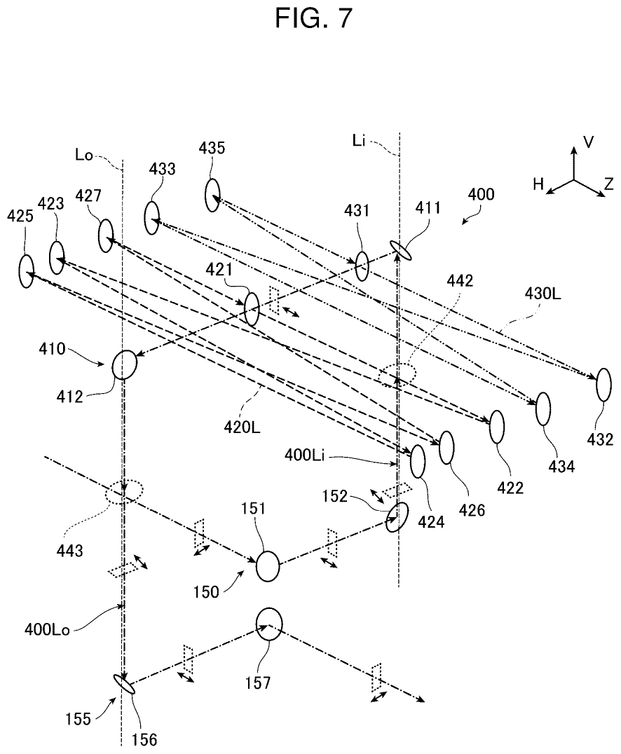

FIG. 7 is a view of a schematic configuration example of the first light guide unit 150, the second light guide unit 155, and the pulse stretcher 400 of the present embodiment as shown in FIG. 3. As shown in FIG. 7, the pulse stretcher 400 of the present embodiment is mainly different from the pulse stretcher 400 of the comparative example in that the light guide optical system 410 does not include the light guide mirrors 413, 414.

In the light guide optical system 410 of the present embodiment, the light guide mirror 412 reflects the laser light reflected by the light guide mirror 411 in the —V direction, and the laser light is output from the pulse stretcher 400.

In the looped optical path 420L of the present embodiment, the beam splitter 421 is arranged on the optical path of the laser light reflected by the light guide mirror 411 and traveling toward the light guide mirror 412 among the optical paths of the laser light in the light guide optical system 410. In the looped optical path 430L of the present embodiment, the beam splitter 431 is arranged on the —H direction side with respect to the beam splitter 421 on the optical path of the laser light reflected by the light guide mirror 411 and traveling toward the light guide mirror 412. The mirrors 432, 434 of the looped optical path 430L and the mirrors 422, 426, 424 of the looped optical path 420L are arranged in the H direction in the order of the mirrors 432, 434, 422, 426, 424. Further, the mirrors 435, 433 of the looped optical path 430L and the mirrors 427, 423, 425 of the looped optical path 420L are arranged in the H direction in the order of the mirrors 435, 433, 427, 423, 425. The looped optical path 420L is located on the H direction side with respect to the looped optical path 430L, and the looped optical path 430L and the looped optical path 420L are aligned in the H direction. The incoming optical path 400Li is located on the side opposite to the maintenance panels 115, 116 side with respect to the optical axis of the laser light transmitted through the output coupling mirror 370, and the outgoing optical path 400Lo is located on the maintenance panels 115, 116 side with respect to the optical axis of the laser light transmitted through the output coupling mirror 370. The looped optical paths 420L, 430L are sandwiched between the first straight line Li along the incoming optical path 400Li and the second straight line Lo along the outgoing optical path 400Lo.

In the second light guide unit 155 of the present embodiment, the high reflection mirror 156 is arranged on the optical path of the laser light output from the pulse stretcher 400, and is located on the —V direction side with respect to the high reflection mirror 151. The high reflection mirror 156 reflects the laser light output from the pulse stretcher 400 in the —H direction. The high reflection mirror 157 is arranged on the optical path of the laser light reflected by the high reflection mirror 156. The high reflection mirror 157 is located on the —V direction side with respect to the high reflection mirror 151, and the high reflection mirror 157 and the high reflection mirror 151 are aligned in the V direction. The high reflection mirror 157 reflects the laser light reflected by the high reflection mirror 156 in the Z direction, and the laser light travels to the sub-pulse stretcher 500. The optical axis of the laser light traveling from the high reflection mirror 157 to the sub-pulse stretcher 500 is substantially parallel to the optical axis of the laser light being transmitted through the output coupling mirror 370, and is located on the −V direction side with respect to the optical axis.

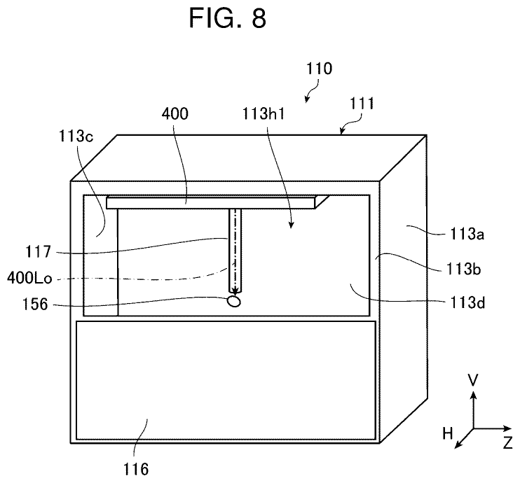

FIG. 8 is a schematic view showing a schematic configuration example of the housing 110 of the present embodiment. In the housing 110 shown in FIG. 8, the maintenance panel 115 is removed. The housing 110 of the present embodiment further includes an optical path pipe 117. The optical path pipe 117 is a cylindrical member extending in a direction parallel to the V direction, and covers the outgoing optical path 400Lo. An end portion of the optical path pipe 117 on the side toward the case 440 is attached to the case 440 in a detachably attachable manner. Since the case 440 is supported by the main body portion 111 of the housing 110, the optical path pipe 117 is attached to the main body portion 111 via the case 440 in a detachably attachable manner. Here, the optical path pipe 117 may be attached directly to the main body portion 111 in a detachably attachable manner. The optical path pipe 117 and the outgoing optical path 400Lo covered by the optical path pipe 117 overlap the opening 113h1.

### 3.2 Operation

The laser light entering the pulse stretcher 400 is incident on the light guide mirror 411 so that the first linear polarization in the laser light becomes S polarization, and is reflected by the light guide mirror 411 toward the light guide mirror 412. The laser light reflected by the light guide mirror 411 is incident on the light guide mirror 412 so that the first linear polarization in the laser light becomes S polarization, is reflected by the light guide mirror 412, and is output from the lower side of the pulse stretcher 400 on which the laser light is incident. The pulse width of the laser light propagating as being reflected sequentially by the light guide mirrors 411, 412 is extended by each of the looped optical paths 420L, 430L, and the laser light whose pulse width has been extended is output from the pulse stretcher 400, and travels to the high reflection mirror 156.

### 3.3 Effect

As described above, there may be a case that the pulse stretcher 400 is positioned with reference to the incoming optical path 400Li and the outgoing optical path 400Lo. For each of the mirrors 422 to 427 and 432 to 435 configuring the looped optical paths 420L, 430L, a short distance among the distance to the incoming optical path 400Li and the distance to the outgoing optical path 400Lo is defined as a specific distance of the corresponding mirror. In this case, when the specific distance of the mirror is increased, the distance from the incoming optical path 400Li and the outgoing optical path 400Lo which are the references tends to be larger, and the mirror tends to be easily deviated from the designed position. In the pulse stretcher 400 of the present embodiment, the looped optical paths 420L, 430L are arranged so as to be sandwiched between the first straight line Li along the incoming optical path 400Li and the second straight line Lo along the outgoing optical path 400Lo. Therefore, the specific distance of the mirror having the largest specific distance among the mirrors 422 to 427 and 432 to 435 can be made shorter as compared with the case in which the incoming optical path 400Li and the outgoing optical path 400Lo are located on one side with respect to the looped optical paths 420L, 430L as in the pulse stretcher 400 of the comparative example. Therefore, according to the gas laser device 100 of the present embodiment, the positions of the mirrors 422 to 427 and 432 to 435 can be suppressed from being deviated from the designed position, and the performance of the laser light can be suppressed from being deviated from the designed value.

In the pulse stretcher 400 of the present embodiment, the outgoing optical path 400Lo is located on the maintenance panels 115, 116 side with respect to the optical axis of the laser light output from the chamber device CH3 and transmitted through the output coupling mirror 370. The incoming optical path 400Li is located on the side opposite to the maintenance panels 115, 116 side with respect to the above-described optical axis. Further, the outgoing optical path 400Lo overlaps the opening 113h1. Therefore, in the present embodiment, the position of the opening 113h1 does not have to be considered in designing the optical path of the laser light from the chamber device CH3 to the outside of the housing 110. Therefore, according to the gas laser device 100 of the present embodiment, the optical path of the laser light output from the pulse stretcher 400 to the outside of the housing 110 is suppressed from becoming complicated, and the number of mirrors can be reduced. Therefore, the loss of the laser light in the light guide optical system 410 can be reduced. Here, the outgoing optical path 400Lo may not overlap the openings 113h1, 113h2.

In the pulse stretcher 400 of the present embodiment, the housing 110 includes the optical path pipe 117 that covers the outgoing optical path 400Lo and is attached to the main body portion 111 in a detachably attachable manner. Therefore, according to the gas laser device 100 of the present embodiment, it is possible to suppress the difficulty of taking in and out of the device, such as the chamber device CH3 accommodated in the housing 110, while protecting the device. Here, the housing 110 may not include the optical path pipe 117.

In the pulse stretcher 400 of the present embodiment, the looped optical path 420L and the looped optical path 430L are aligned in a direction parallel to the H direction, which is a direction non-parallel to the incoming optical path 400Li. Therefore, according to the gas laser device 100 of the present embodiment, it is possible to suppress the gas laser device 100 from becoming large in a direction parallel to the incoming optical path 400Li. Here, the looped optical path 420L and the looped optical path 430L may not be aligned in a direction non-parallel to the incoming optical path 400Li.

The pulse stretcher 400 of the present embodiment includes the case 440. The case 440 accommodates the light guide optical system 410 and the looped optical paths 420L, 430L, and supports the plurality of light guide mirrors 411, 412, the beam splitters 421, 431, and the plurality of mirrors 422 to 427 and 432 to 435. In the case 440, the inlet hole 442 through which the laser light from the chamber device CH3 enters and the outlet hole 443 through which the laser light is output are formed. The incoming optical path 400Li and the outgoing optical path 400Lo can be separated from each other because the first straight line Li along the incoming optical path 400Li and the second straight line Lo along the outgoing optical path 400Lo sandwich the looped optical paths 420L, 430L. According to the gas laser device 100 of the present embodiment, when the pulse stretcher 400 is positioned with reference to the inlet hole 442 and the outlet hole 443, positioning of the pulse stretcher 400 can be easily performed and the arrangement operation can be facilitated. Here, the pulse stretcher 400 may not include the case 440. In this case, for example, the plurality of light guide mirrors 411, 412, the beam splitters 421, 431, and the plurality of mirrors 422 to 427 and 432 to 435 are supported by the main body portion 111 of the housing 110.

In the pulse stretcher 400 of the present embodiment, the light guide optical system 410 includes the light guide mirror 411 as the first light guide mirror and the light guide mirror 412 as the second light guide mirror. The light guide mirror 411 reflects the laser light entering the pulse stretcher 400, and the light guide mirror 412 reflects the laser light reflected by the light guide mirror 411 to output the laser light from the pulse stretcher 400. According to the gas laser device 100 of the present embodiment, as compared with the case in which the light guide optical system 410 includes three or more light guide mirrors, the number of times of reflection of the laser light can be reduced, and a decrease in the light amount of the laser light can be suppressed. The light guide optical system 410 may further include a light guide mirror different from the light guide mirrors 411, 412.

In the pulse stretcher 400 of the present embodiment, the laser light entering the pulse stretcher 400 is incident on the light guide mirror 411 so that the first linear polarization of the laser light becomes S polarization. The laser light reflected by the light guide mirror 411 is incident on the light guide mirror 412 so that the first linear polarization of the laser light becomes S polarization. The reflectance of S polarization tends to be higher than that of P polarization. Therefore, according to the gas laser device 100 of the present embodiment, for example, it is possible to suppress a decrease in the light amount in the light guide mirrors 411, 412 as compared with a case in which the laser light is reflected by being incident on the light guide mirrors 411, 412 so that the first linear polarization in the laser light becomes P polarization. Therefore, according to the gas laser device 100 of the present embodiment, it is possible to suppress a decrease in the light amount of the laser light. Here, the laser light may not be incident on the light guide mirrors 411, 412 so that the first linear polarization of the laser light becomes S polarization.

### 4. Description of Gas Laser Device of Second Embodiment

Next, the gas laser device 100 of a second embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

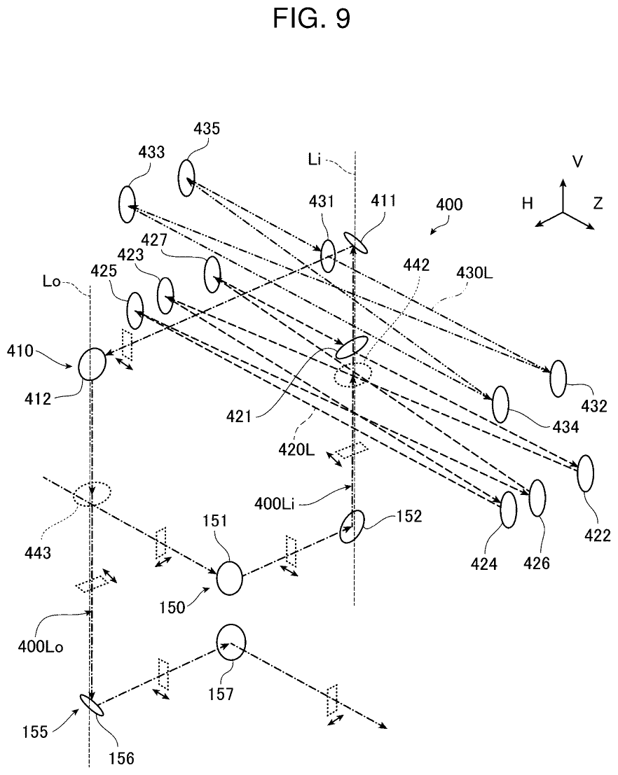

FIG. 9 is a view of a schematic configuration example of the first light guide unit 150, the second light guide unit 155, and the pulse stretcher 400 of the present embodiment as shown in FIG. 3. As shown in FIG. 9, the pulse stretcher 400 of the present embodiment is mainly different from the pulse stretcher 400 of the first embodiment in that the beam splitter 421 of the looped optical path 420L is arranged on the optical path of the laser light entering the pulse stretcher 400 and traveling toward the light guide mirror 411.

In the present embodiment, the looped optical path 420L is located on the −V direction side with respect to the looped optical path 430L. Further, the looped optical path 420L and the looped optical path 430L overlap each other in a direction parallel to the incoming optical path 400Li. Similarly to the first embodiment, the looped optical paths 420L, 430L are sandwiched between the first straight line Li along the incoming optical path 400Li and the second straight line Lo along the outgoing optical path 400Lo.

### 4.2 Effect

In the pulse stretcher 400 of the present embodiment, as described above, the looped optical path 420L and the looped optical path 430L overlap each other in a direction parallel to the incoming optical path 400Li. Therefore, according to the gas laser device 100 of the present embodiment, it is possible to suppress the gas laser device 100 from becoming large in a direction perpendicular to the incoming optical path 400Li. Here, the looped optical path 420L and the looped optical path 430L may not overlap each other in a direction parallel to the incoming optical path 400Li.

### 5. Description of Gas Laser Device of Third Embodiment

Next, the gas laser device 100 of a third embodiment will be described. Any component same as that described above is denoted by an identical reference sign, and duplicate description thereof is omitted unless specific description is needed. Further, in some drawings, a part of a member may be omitted or simplified for easy viewing.

### 5.1 Configuration

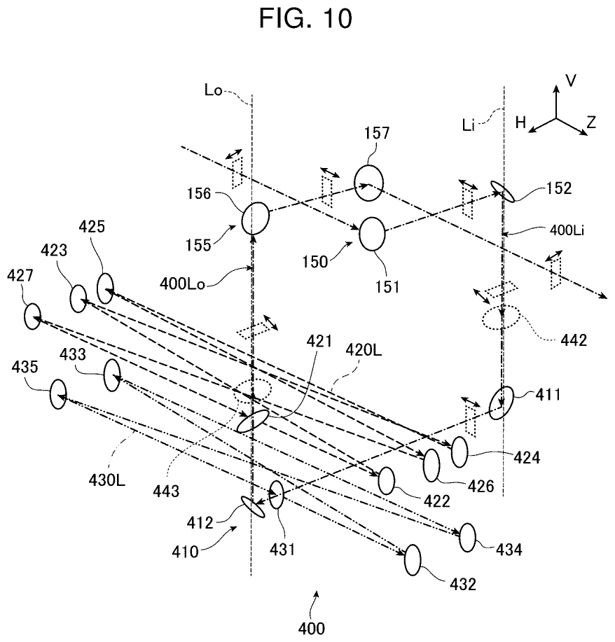

FIG. 10 is a view of a schematic configuration example of the first light guide unit 150, the second light guide unit 155, and the pulse stretcher 400 of the present embodiment as shown in FIG. 3. As shown in FIG. 10, the gas laser device 100 of the present embodiment is mainly different from the gas laser device 100 of the first embodiment in that the pulse stretcher 400 is arranged on the —V direction side, which is the lower side from the optical axis of the laser light output from the chamber device CH3 and transmitted through the output coupling mirror 370.

In the first light guide unit 150 of the present embodiment, the high reflection mirror 151 reflects the laser light from the output coupling mirror 370 in the —H direction. The high reflection mirror 152 reflects the laser light reflected by the high reflection mirror 151 in the —V direction, and the laser light enters the pulse stretcher 400.

In the light guide optical system 410 of the present embodiment, the light guide mirror 411 reflects the laser light entering the pulse stretcher 400 in the H direction. The light guide mirror 412 reflects the laser light reflected by the light guide mirror 411 in the V direction, and the laser light is output from the pulse stretcher 400. That is, the laser light enters the pulse stretcher 400 from above, and the pulse stretcher 400 outputs the laser light upward. Although not illustrated, in the case 440 of the present embodiment, the inlet hole 442 and the outlet hole 443 are provided on the upper wall of the case 440.

In the looped optical path 420L of the present embodiment, the beam splitter 421 is arranged on the optical path of the laser light reflected by the light guide mirror 412 and traveling toward the high reflection mirror 156 among the optical paths of the laser light in the light guide optical system 410. The mirrors 422, 424, 426 are aligned in the −H direction in the order of the mirrors 422, 426, 424, and the mirrors 423, 425, 427 are aligned in the —H direction in the order of the mirrors 427, 423, 425.

In the looped optical path 430L of the present embodiment, the beam splitter 431 is arranged on the optical path of the laser light reflected by the light guide mirror 411 and traveling toward the light guide mirror 412 among the optical paths of the laser light in the light guide optical system 410. The mirrors 432, 434 are aligned in the −H direction in the order of the mirrors 432, 434, and the mirrors 433, 435 are aligned in the —H direction in the order of the mirrors 435, 433.

The looped optical path 420L is located on the V direction side with respect to the looped optical path 430L. Further, the looped optical path 420L and the looped optical path 430L overlap each other in a direction parallel to the incoming optical path 400Li. Similarly to the first embodiment, the looped optical paths 420L, 430L are sandwiched between the first straight line Li along the incoming optical path 400Li and the second straight line Lo along the outgoing optical path 400Lo.

In the second light guide unit 155 of the present embodiment, the high reflection mirror 156 is arranged on the optical path of the laser light output from the pulse stretcher 400, and the high reflection mirror 156 is located on the V direction side with respect to the optical axis of the laser light transmitted through the output coupling mirror 370. The high reflection mirror 156 reflects the laser light output from the pulse stretcher 400 in the —H direction. The high reflection mirror 157 is arranged on the optical path of the laser light reflected by the high reflection mirror 156. The high reflection mirror 157 is located on the V direction side with respect to the high reflection mirror 151, and the high reflection mirror 151 and the high reflection mirror 157 are aligned in the V direction. The high reflection mirror 157 reflects the laser light reflected by the high reflection mirror 156 in the Z direction, and the laser light travels to the sub-pulse stretcher 500. The optical axis of the laser light traveling from the high reflection mirror 157 to the sub-pulse stretcher 500 is substantially parallel to the optical axis of the laser light being transmitted through the output coupling mirror 370, and is located on the V direction side with respect to the optical axis.

### 5.2 Effect

The pulse stretcher 400 of the present embodiment is arranged in the −V direction side, which is the lower side from the optical axis of the laser light output from the chamber device CH3 and transmitted through the output coupling mirror 370. According to the gas laser device 100 of the present embodiment, as compared with the case in which the pulse stretcher 400 is arranged above the optical axis, the position of the pulse stretcher 400 can be suppressed from becoming too high, and for example, maintenance of the pulse stretcher 400 can be facilitated. Here, the position of the pulse stretcher 400 with respect to the optical axis is not limited.

Although the above embodiments have been described as an example, the present disclosure is not limited thereto, and can be modified as appropriate.

In the above embodiments, the pulse stretcher 400 including the two looped optical paths 420L, 430L has been exemplified. However, the number of the looped optical paths is not limited.

In the above embodiments, the looped optical path 420L including the beam splitter 421 and the six mirrors 422 to 427 and the looped optical path 430L including the beam splitter 431 and the four mirrors 432 to 435 are exemplified. However, the number of mirrors configuring each looped optical path is not limited.

Further, in the above embodiments, the first light guide unit 150 including the two high reflection mirrors 151, 152 and the second light guide unit 155 including the two high reflection mirrors 156, 157 have been exemplified. However, as long as the laser light output from the chamber device CH3 enters the pulse stretcher 400, the number of high reflection mirrors included in each of the first light guide unit 150 and the second light guide unit 155 is not limited. Further, the gas laser device 100 may not include at least one of the first light guide unit 150 and the second light guide unit 155.

Further, in the above embodiments, the pulse stretcher 400 in which the incoming optical path 400Li and the outgoing optical path 400Lo are substantially parallel to the vertical direction has been described. However, at least one of the incoming optical path 400Li and the outgoing optical path 400Lo may be non-parallel to the vertical direction.

Further, in the above-described embodiments, the beam splitters 421, 431 causing the reflected laser light to propagate to the looped optical paths 420L, 430L respectively are exemplified. However, the laser light transmitted through the beam splitters 421, 431 may propagate to the looped optical paths 420L, 430L respectively. In this case, the beam splitters 421, 431 serve as a part of the light guide optical system 410, and the looped optical paths 420L, 430L serve for both the light guide optical system 410 and the beam splitters 421, 431.

Further, in the above-described embodiments, the pulse stretcher 400 in which the outgoing optical path 400Lo is located on the maintenance panels 115, 116 side with respect to the optical axis of the laser light output from the chamber device CH3 and transmitted through the output coupling mirror 370 has been exemplified. However, the incoming optical path 400Li may be located on the maintenance panels 115, 116 side with respect to the above-described optical axis. In this case, the incoming optical path 400Li may overlap the opening 113h1. When the incoming optical path 400Li overlaps the opening 113h1, the position of the opening 113h1 may not be considered in designing the optical path of the laser light from the chamber device CH3 to the pulse stretcher 400. Therefore, it is possible to suppress the optical path from becoming complicated.

Further, in the above-described embodiments, the pulse stretcher 400 accommodated in the main body portion 111 of the housing 110 has been exemplified. However, the pulse stretcher 400 may be arranged outside the housing 110.

In the above-described embodiments, the gas laser device 100 including the laser oscillator 130 and the amplifier 160 has been exemplified. However, the gas laser device 100 may not include the amplifier 160. In this case, for example, the laser light output from the chamber device CH1 and transmitted through the output coupling mirror 70 enters the pulse stretcher 400.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device comprising:
a chamber device including a pair of electrodes at an internal space thereof at which a laser gas is enclosed, and configured to output pulse laser light; and
a pulse stretcher which includes a looped optical path including a beam splitter and a plurality of mirrors, and a light guide optical system including a plurality of light guide mirrors, and which the pulse laser light output from the chamber device enters,
the light guide system being configured to cause the pulse laser light having entered the pulse stretcher to be output from the pulse stretcher via the beam splitter, and
the looped optical path being configured to return a part of the pulse laser light having entered the beam splitter to the beam splitter via the plurality of mirrors to cause the part of the pulse laser light to overlap another part of the pulse laser light having entered the beam splitter, and being arranged to be sandwiched between a first straight line along an incoming optical path that is an optical path of the pulse laser light entering the pulse stretcher and a second straight line along an outgoing optical path that is an optical path of the pulse laser light output from the pulse stretcher.

2. The gas laser device according to claim 1,
further comprising a housing that accommodates the chamber device, and includes a main body portion which is provided with an opening allowing the chamber device to be taken in and out and a maintenance panel which blocks the opening and which is attached to the main body portion in a detachably attachable manner.

3. The gas laser device according to claim 2,
wherein one of the incoming optical path and the outgoing optical path is located on the maintenance panel side with respect to an optical axis of the pulse laser light output from the chamber device, and the other of the incoming optical path and the outgoing optical path is located on a side opposite to the maintenance panel side with respect to the optical axis.

4. The gas laser device according to claim 3,
wherein the one of the incoming optical path and the outgoing optical path overlaps the opening.

5. The gas laser device according to claim 4,
wherein the housing further includes an optical path pipe which covers the one of the incoming optical path and the outgoing optical path and which is attached to the main body portion in a detachably attachable manner.

6. The gas laser device according to claim 1,
wherein the pulse stretcher includes a plurality of the looped optical paths.

7. The gas laser device according to claim 6,
wherein the plurality of looped optical paths overlap each other in a direction parallel to the incoming optical path.

8. The gas laser device according to claim 6,
wherein the plurality of looped optical paths are aligned in a direction non-parallel to the incoming optical path.

9. The gas laser device according to claim 1,
wherein the pulse stretcher accommodates the light guide optical system and the looped optical path, and further includes a case that supports the plurality of light guide mirrors, the beam splitter, and the plurality of mirrors, and
the case is provided with an inlet hole through which the pulse laser light from the chamber device enters, and an outlet hole through which the pulse laser light is output.

10. The gas laser device according to claim 1,
wherein the pulse stretcher is arranged above an optical axis of the pulse laser light output from the chamber device.

11. The gas laser device according to claim 1,
wherein the pulse stretcher is arranged below an optical axis of the pulse laser light output from the chamber device.

12. The gas laser device according to claim 1,
wherein the light guide system includes a first light guide mirror that reflects the pulse laser light having entered the pulse stretcher, and a second light guide mirror that reflects the pulse laser light reflected by the first light guide mirror to output the pulse laser light from the pulse stretcher.

13. The gas laser device according to claim 12,
wherein the pulse laser light having entered the pulse stretcher includes first linear polarization,
the pulse laser light having entered the pulse stretcher is incident on the first light guide mirror so that the first linear polarization of the pulse laser light becomes S polarization, and
the pulse laser light reflected by the first light guide mirror is incident on the second light guide mirror so that the first linear polarization of the pulse laser light becomes S polarization.

14. An electronic device manufacturing method, comprising:
outputting pulse laser light generated by a gas laser device to an exposure apparatus; and
exposing a photosensitive substrate in the exposure apparatus to the pulse laser light output to the exposure apparatus to manufacture an electronic device,
the gas laser device including:
a chamber device including a pair of electrodes at an internal space thereof at which a laser gas is enclosed, and configured to output the pulse laser light; and
a pulse stretcher which includes a looped optical path including a beam splitter and a plurality of mirrors, and a light guide optical system including a plurality of light guide mirrors, and which the pulse laser light output from the chamber device enters,
the light guide system being configured to cause the pulse laser light having entered the pulse stretcher to be output from the pulse stretcher via the beam splitter, and
the looped optical path being configured to return a part of the pulse laser light having entered the beam splitter to the beam splitter via the plurality of mirrors to cause the part of the pulse laser light to overlap another part of the pulse laser light having entered the beam splitter, and being arranged to be sandwiched between a first straight line along an incoming optical path that is an optical path of the pulse laser light entering the pulse stretcher and a second straight line along an outgoing optical path that is an optical path of the pulse laser light output from the pulse stretcher.
